(19) United States
(12) Patent Application Publication
(10) Pub. No.: US 2025/0189561 A1
(43) Pub. Date: Jun. 12, 2025

(54) SYSTEM FOR ESTIMATING VOLTAGE

(71) Applicant: Alberto BAUER, Al Menara (AE)

(72) Inventor: Alberto BAUER, Al Menara (AE)

(21) Appl. No.: 18/849,479

(22) PCT Filed: Apr. 13, 2023
(86) PCT No.: PCT/IT2023/000009

§ 371 Date: Sep. 21, 2024

(30) Foreign Application Priority Data
Apr. 15, 2022 (IT) 102022000007436

(51) Int. Cl. G01R 15/16; G01R 19/00

(52) U.S. Cl. CPC G01R 15/16; G01R 19/0084

(57) ABSTRACT

A system for estimating the value of the electrical voltage relating to a live n element ET. The system comprises a first capacitor C1.sx, a second capacitor C1.dx, a third capacitor C2.sx, a fourth capacitor C2.dx, a fifth capacitor C3.dx. The System may include a modular structure.

### FIELD OF INVENTION

The present invention concerns the field of Systems for estimating the value of the electric voltage relative to a live element.

More particularly, the present invention relates to a system for estimating the voltage of a live element, in which, for example, said live element can be a conductor, or a bar, or a bushing, or other live element.

### Background of the Invention

Currently are known systems for estimating the voltage value of a live element. These systems have a series of drawbacks.

A first drawback is due to the fact that they do not allow a correct and/or safe estimate of the voltage value of the live element to be maintained over time, due to the aging of the electrical components and/or other reasons.

A second drawback is due to the fact that in order to maintain a given measurement precision over time, these systems require maintenance which is difficult and costly.

A third drawback is due to the fact that the maintenance and/or repair operations of said systems can be carried out only if the element subject to measurement is not live.

A fourth drawback is due to the fact that the maintenance and/or repair operations of said systems can be performed only and exclusively by expert workers.

### Exhibition of the Invention

The object of the present invention is therefore to solve the aforementioned drawbacks.

The invention, which is characterized by the claims, solves the problem of creating a system for estimating the value of the electric voltage relating to a live element, in which said system is characterized in that it comprises: a first capacitor comprising a respective first pole and a second pole; a second capacitor comprising a respective first pole and a second pole; a third capacitor comprising a respective first pole and a second pole; a fourth capacitor comprising a respective first pole and a second pole; a fifth capacitor comprising a respective first pole and a second pole; wherein said first capacitor has its first pole connected to said live element; wherein said second capacitor has its first pole connected to said live element; wherein said third capacitor has its first pole connected to the second pole of the first capacitor and its second pole connected to ground; wherein said fourth capacitor has its first pole connected to the second pole of the second capacitor and its second pole connected to the first pole of the fifth capacitor; wherein said fifth capacitor has its second pole connected to ground; wherein said first capacitor supplies on its second pole and/or along the respective conducting wire which connects it to the third capacitor a voltage value defined herein as first voltage value; wherein said fourth capacitor provides to its second pole and/or along the respective conducting wire which connects it to the fifth capacitor a voltage value defined herein as fourth voltage value.

### BRIEF DESCRIPTION OF THE DRAWINGS

Further characteristics and advantages of the present invention will be more evident from the following description of some of its preferred practical embodiments, given here by way of purely non-limiting example, made with reference to the figures of the attached drawings in which:

FIG. 1 schematically illustrates a first embodiment of the system object of the present invention;

FIG. 2 schematically illustrates a second embodiment of the system object of the present invention;

FIGS. 3 and 4 illustrate waveforms of electrical voltage.

### PREFERRED EXAMPLE FORMS OF IMPLEMENTATION PRACTICES

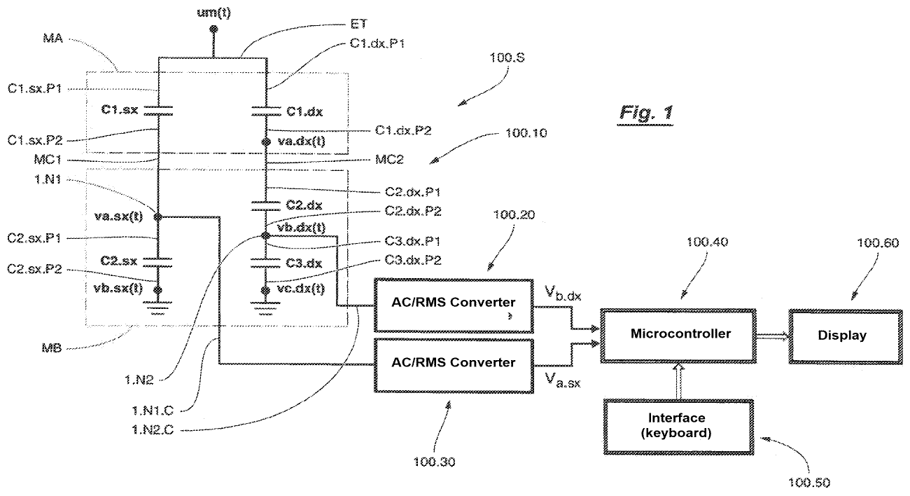

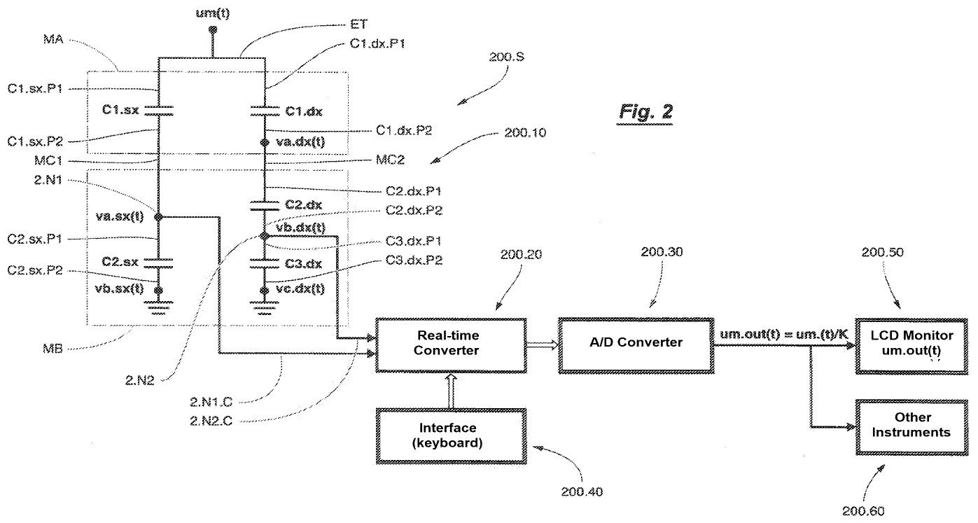

With reference to FIGS. 1 and 2, the system 100.S/200.S object of the present invention, for estimating the value of the electric voltage relating to a live element ET, configures a schematic electric circuit 100.10/200.10 which substantially comprises: a first capacitor C1.sx comprising a respective first pole C1.sx.p1 and a second pole C1.sx.p2; a second capacitor C1.dx comprising a respective first pole C1.dx.p1 and a second pole C1.dx.p2; a third capacitor C2.sx comprising a respective first pole C2.sx.p1 and a second pole C2.sx.p2; a fourth capacitor C2.dx comprising a respective first pole C2.dx.p1 and a second pole C2.dx.p2; a fifth capacitor C3.dx comprising a respective first pole C3.dx.p1 and a second pole C3.dx.p2.

With reference to the components described above and always schematically: the first capacitor C1.sx has its first pole C1.sx.p1 connected to said live element ET; the second capacitor C1.dx has its first pole C1.dx.p1 connected to said live element ET; the third capacitor C2.sx has its first pole C2.sx.p1 connected to the second pole C1.sx.p2 of the first capacitor C1.sx preferably by means of a respective connecting conductor MC1 and its second pole C2.sx.p2 connected to the ground; the fourth capacitor C2.dx has its first pole C2.dx.p1 connected to the second pole C1.dx.p2 of the second capacitor C1.dx preferably by means of a respective connecting conductor MC2 and its second pole C2.dx.p2 connected to the first pole C3.dx.p1 of the fifth capacitor C3.dx; the fifth capacitor C3.dx has its second pole C3.dx.p2 connected to the ground.

With reference to the connections described above, again schematically: the first capacitor C1.sx supplies on the second pole C1.sx.p2 and/or along the respective conducting wire C1.sx.p2_MC1_C2.sx.p1 which connects it to the third capacitor C2.sx, as for example on a first node indicated with 1.N1 in FIG. 1 and with 2.N1 in FIG. 2, a voltage value, va.sx(t), defined here as the first voltage value; the second capacitor C1.dx supplies on its second pole C1.dx.p2 and/or along the respective conductor wire which connects it to the fourth capacitor C2.dx a voltage value, va.dx(t), here defined as second voltage value; the third capacitor C2.sx provides on its second pole C2.sx.p2 and along the respective conducting wire which connects it to the ground a voltage value, vb.sx(t), defined here as third voltage value; the fourth capacitor C2.dx supplies on its second pole C2.dx.p2 and/or along the respective conducting wire C2.dx.p2_C3.dx.p1 which connects it to the fifth capacitor C3.dx, as for example on a second node, indicated by 1.N2 in FIG. 1 and indicated by 2.N2 in FIG. 2, a voltage value, vb.dx(t), defined here as the fourth voltage value; the fifth capacitor C3.dx provides on its second pole C3.dx.p2 and along the conducting wire which connects it to earth a voltage value, vc.dx(t), defined here as the fifth voltage value.

With reference to FIG. 1, always preferably, the system 100.S can further comprise the following components: a first AC/RMS converter 100.20 connected by means of a respective conductor 1.N2.C to the second node 1.N2 positioned along the connection between the fourth capacitor C2.dx and the fifth capacitor C3.dx; a second AC/RMS converter 100.30 connected by means of a respective conductor 1.N1.C to the first node 1.N1 positioned along the connecting conductor between the first capacitor C1.sx and the third capacitor C2.sx; a microcontroller 100.40 connected to said first and second converters 100.20 and 100.30, a user interface (keyboard) 100.50 for data entry, such as for example entry of capacitor capacitance values connected to said microcontroller 100.40; a display 100.60 also connected to said microcontroller 100.40.

With reference to FIG. 2, always preferably, the system 200.S can further comprise the following components: a Real-Time Microcontroller 200.20 connected via a respective conductor 2.N2.C to the second node 2.N2 positioned along the connection conductor between the fourth capacitor C2.dx and the fifth capacitor C3.dx and connected by means of a conductor 2.N1.C to the first node 2.N1 positioned along the connecting conductor between the first capacitor C1.sx and the third capacitor C2.sx; a Digital-Analog Converter 200.30 connected to said real_time microcontroller 200.20; an user interface (keyboard) 200.40, for entering data, such as for example for entering data relating to the transformation ratio “k”, connected to said microcontroller 200.20; and an LCD monitor 200.50; other instruments 200.60.

In the system object of the present invention, 100.S/200.S, preferably, the first capacitor C1.sx and the second capacitor C1.dx are two equal and/or identical capacitors.

According to a further embodiment of the system, the first capacitor C1.sx and the second capacitor C1.dx are two capacitors having a respective dielectric identical to each other and/or a respective dielectric which is not identical (i.e. different) but nevertheless having the same characteristics in relation to the change in these characteristics if these two capacitors are subjected, over time, to the same functional and environmental vicissitudes (operation, temperature, humidity, etc.) and aging over time.

According to a further embodiment, the fourth capacitor C2.dx has a capacitance value having the same order of magnitude with respect to the first capacitor C1.sx and/or with respect to the second capacitor C1.dx.

Furthermore, as an embodiment variant, for example, the first capacitor C1.sx and the second capacitor C1.dx could be two capacitors (two capacities) with a known relationship between them, i.e. two capacitors C1.sx and C1.dx which have a respective capacitance value, Vdc_C1.sx and Vdc_C1.dx, where these two values have a ratio, . . . C1.sx/C1.dx=known_r_value . . . , then consider said known_r_value in the equation/calculation for the estimate of the voltage relating to the element under voltage ET.

Always preferably, the system also includes the characteristic of subjecting the first capacitor C1.sx and the second capacitor C1.dx to the same operating and/or exercise and/or environmental and/or aging conditions (subject to the same vicissitudes) after their installation, i.e. in the subsequent passage of time, such as, for example, providing these two capacitors C1.sx and C1.dx connected and/or assembled and/or positioned and/or placed and/or arranged in such a way as to implement said characteristic.

By means of the 100.S/200.S system described above, the estimate of the voltage value of the element under voltage ET can be calculated in various ways using the following values: 1)_at least one voltage value relating to a first point/node 1.N1/2.N1 positioned along the conducting wire C1.sx.P2_MC1_C2.sx.p1 which connects the first capacitor C1.sx to the third capacitor C2.sx; 2)_at least one voltage value relating to a second point/node 1.N2/2.N2 positioned along the conducting wire C2.dx.p2_C3.dx.p1 which connects the fourth capacitor C2.dx to the fifth capacitor C3.dx; 3)_at least one capacitance value of the third capacitor C2.sx; 4)_at least one capacitance value of the fourth capacitor C2.dx; 5)_at least one capacitance value of the fifth capacitor C3.dx.

According to a first exemplary embodiment of the system object of the present invention, see FIG. 1, system 100.S, the value called voltage of the element ET is calculated using the following equation (equation_1):

$$… um = \frac{Va . sx . Vb . dx . ( C 2. sx . C 3. dx + C 2. sx . C 2. dx - C 2. dx . C 3. dx )}{C 2. dx . ( Va . sx . C 2. sx - Vb . dx . C 3. dx )}$$

where
Um=RMS value of the voltage relating to said element under voltage ET
Va.sx=Effective value of the voltage relating to the second pole C1.sx.p2 of the first capacitor C1.sx and/or relating to a first node 1.N1 positioned along the conducting wire C1.sx.P2_MC1_C2.sx.p1 which connects the first capacitor C1.sx to third capacitor C2.sx;
Vb.dx=Effective value of the voltage relating to the second pole C2.dx.p2 of the fourth capacitor C2.dx and/or relating to a second node 1.N2 positioned along the conducting wire C2.dx.p2_C3.dx.p1 which connects the fourth capacitor C2.dx to fifth capacitor C3.dx;
C2.sx=Capacitance value of the third capacitor C2.sx;
C2.dx=Capacitance value of the fourth capacitor C2.dx;
C3.dx=Capacitance value of the fifth capacitor C3.dx

According to a second exemplary embodiment of the system object of the present invention, see FIG. 2, system 200.S, the voltage value of the ET element is calculated using the following equation (equation_2):

$$um ( t ) = \frac{va . sx ( t ) . vb . dx ( t ) . ( C 2. sx . C 3. dx + C 2. sx . C 2. dx - C 2. dx . C 3. dx )}{C 2. dx . ( va . sx ( t ) . C 2. sx - vb . dx ( t ) . C 3. dx )}$$

where
um(t)=Estimated value of the instantaneous primary voltage relating to said element under voltage ET
va.sx(t)=Value of the instantaneous voltage relating to the second pole C1.sx.p2 of the first capacitor C1.sx and/or relating to a first node 2.N1 positioned along the conducting wire C1.sx.P2_MC1_C2.sx.p1 which connects the first capacitor C1.sx to the third capacitor C2.sx;
vb.dx(t)=Value of the instantaneous voltage relating to the second pole C2.dx.p2 of the fourth capacitor C2.dx) and/or relating to a second node 2.N2 positioned along the conducting wire C2.dx.p2_C3.dx. p1 which connects the fourth capacitor C2.dx to the fifth capacitor C3.dx;
C2.sx=Capacitance value of the third capacitor C2.sx;
C3.dx=Capacitance value of the fifth capacitor C3.dx
C2.dx=Capacitance value of the fourth capacitor C2.dx.

### Modular Structure

With reference to FIGS. 1 and 2, the system 100.S/200.S can preferably comprise: a first electric module MA; a second electric module MB; connection means MC1_MC2 for connecting the modules together, such as for example the aforementioned first and second connection means MC1 and MC2; wherein the first module MA comprises the first capacitor C1.sx and the second capacitor C1.dx; wherein the second electric module MB comprises other components, such as, for example, the third capacitor C2.sx, the fourth capacitor C2.dx and the fifth capacitor C3.dx; and wherein said connection means, for example the first and second connection means MC1 and MC2, are able to connect said first module MA with respect to said second module MB.

In the example illustrated in FIG. 1, in the second module MB there is a first node 1.N1, preferably positioned on the first pole C2.sx.p1 of the third capacitor C2.sx, and a relative associated first cable 1.N1.C, in order to transmit the relative signal va.sx(t) preferably outside the module MB and/or to a second AC/RMS converter 100.30.

Again in the example illustrated in FIG. 1, in the second module MB there is also a second node 1.N2, preferably positioned along the connecting wire C2.dx.p2_C3.dx.p1 between the fourth capacitor C2.dx and the fifth capacitor C3.dx, and a relative associated second cable 1.N2.C, in order to transmit the relative signal va.dx(t) preferably outside the module MB and/or to a first converter ac/rms 100.20.

In the exemplary form illustrated in FIG. 2, in the second module MB there is a first node 2.N1, preferably positioned on the first pole C2.sx.p1 of the third capacitor C2.sx, and a relative associated first cable 2.N1.C, in order to transmit the relative signal va.sx(t) preferably outside the module MB and/or to a Real-Time Microcontroller 200.20.

Also in the exemplary form shown in FIG. 2, in the second module MB there is a second node 2.N2, preferably positioned along the connecting wire C2.dx.p2_C3.dx.p1 between the fourth capacitor C2.dx and the fifth capacitor C3.dx, and a relative associated second cable 2.N2.C, in order to transmit the relative signal va.dx(t) preferably outside the module MB and/or to a Real-Time Microcontroller 200.20.

With reference to FIGS. 1 and 2, through this technical solution comprising the two modules MA and MB, the first electric module MA can be positioned in a separated and/or independent manner with respect to the positioning of the second electric module MB, the first connection means MC1 connect the second pole C1.sx.p2 of the first capacitor C1.sx with the first pole C2.sx.p1 of said third capacitor C2.sx, and the second connection means MC2 connect the second pole C1.dx.p2 of the second capacitor C1.dx with the first pole C2.dx.p1 of the fourth capacitor C2.dx.

Preferably, said first module MA is positioned in such a way that the first capacitor C1.sx and the second capacitor C1.dx will be subjected, over time, to the same vicissitudes.

More particularly, always preferably, by means of this modular structure system, the first electric module MA can be positioned in such a way that the first capacitor C1.sx and the second capacitor C1.dx will be subjected, over time, after their installation, to the same environmental vicissitudes (temperature, humidity, radiation) and also to the same operating vicissitudes (electrical conditions, loads, etc.), as for example fixed to the same ET conductor supported on the top of a pylon and, therefore, subject to bad weather that will follow over time, while the second MB module can be positioned in a more accessible and/or sheltered place, such as for example inside an electrical substation.

### Components

With reference to the first and second embodiments, 100.S/200.S, illustrated in the respective FIGS. 1 and 2, as an exemplifying but non-limiting embodiment, the system described above could comprise: _as first capacitor C1.sx, a capacitor manufactured by Vishay company, product no. 715C30KTT33, having the following characteristics: ceramic capacitor, capacity: 330 pF, ac rated voltage: 20 kV; _as second capacitor C1.dx, a capacitor manufactured by Vishay company, product no. 715C30KTT33 having the following characteristics: ceramic capacitor, capacity: 330 pF, ac rated voltage: 20 kV; as third capacitor C2.sx, a capacitor manufactured by the Kemet company, product no. Type C1002_X7R, having the following characteristics; ceramic capacitor, capacity: 590 nF, rated voltage 100V, NPO; _as fourth capacitor C2.dx, a capacitor manufactured by the Kemet firm, product no. Type C1002_X7R, having the following characteristics; ceramic capacitor, capacitance: 20 pF, rated voltage: 50V, NPO; _as fifth capacitor C3.dx, a capacitor manufactured by the Kemet company, product no. C1812C683J1GACAUTO, having the following characteristics: ceramic capacitor, capacity: 630 nF, rated voltage: 100V, NPO, ceramic.

In this context, it is specified that the devices C1.sx, C1.dx, C2.sx, C2.dx and C3.dx specified above, by way of example, can also assume other embodiments, suitable for performing the same function, without departing from the inventive concepts protected by the present invention.

With particular reference to the first embodiment, illustrated in FIG. 1, system 100.S, as an exemplifying but non-limiting embodiment, the system described above could comprise: _as the first AC/RMS 100.20 converter, a device able to convert an alternating voltage waveform into a direct voltage, i.e. capable of calculating (converting) the effective value of an alternating quantity which reaches the input of said first converter device 100.20, such as for example a commercial converter device known as model AD736 produced by the company Analog Devices; _as second AC/RMS converter 100.30, a converter device identical and/or analogous to the previous first converter 100.20; _as microcontroller 100.40, a device suitable for calculating mathematical formulas, in which said microcontroller 100.40 is always preferably equipped with an analog-digital converter for acquiring instantaneous signals, converting them into digital numbers, performing the operations and, therefore, communicating the results to an external display, such as for example a commercial microcontroller known as model PIC24FJ128GC006 manufactured by Microchip Technologies Inc.; _as display 100.50, a device for presenting information, preferably a liquid crystal display of the 4-line type with 20 characters per line, such as for example an LCD_20x4Y commercial display produced by the Gravitech company; _as user interface (keyboard) 100.60, a keyboard or other similar device able to allow data and/or commands to be entered into the aforementioned Microcontroller 100.40.

In this context, it is specified that the devices 100.20, 100.30, 100.40, 100.50 and 100.60, specified above by way of example, can also assume other embodiments, capable of performing the same functions, without departing from the inventive concepts protected by the present invention.

With particular reference to the second embodiment, illustrated in FIG. 2, as an exemplifying but non-limiting embodiment, the system described above could comprise: as a Real-Time Microcontroller 200.20, a device suitable for calculating formulas and modifying of signals acquired with an internal analog-digital converter, also having characteristics that allow it to operate with real-time operating systems, such as for example a Reat-Time microcontroller known as model DSPIC33FJ16GS402_H/MM produced by Microchip Technologies Inc.; such as Digital-Analog Converter 200.30, a Digital-Analog converter device suitable for converting a series of data in digital format into an instantaneous-analog signal, such as for example a commercial Digital-Analog Converter known as model DAC121 S101 CIMM/NOPB manufactured by the company Texas Instruments; as user interface (keyboard) 200.40, a keyboard or other similar device able to allow data and/or commands to be entered into the aforementioned microcontroller 200.20.

In this context, it is specified that the devices 200.20, 200.30, 200.40, specified above by way of example, can also assume other embodiments, suitable for performing the same functions, without departing from the inventive concepts protected by the present invention.

### First Example of Calculation—System 100.S of FIG. 1

By way of example, with reference to the system 100.S of FIG. 1, using the components as indicated above and substantially: a first capacitor C1.sx having capacity of 330 pF; a second capacitor C1.dx having capacity of 330 pF; a third capacitor C2.sx having a capacity of 590 nF; a fourth capacitor C2.dx having capacity of 20 pF; a fifth capacitor C3.dx having capacity of 630 nF; by applying the 100.S system to an element having voltage, the following values were detected

at the output of the second converter 100.30 a Va.sx value=0.25312 V

at the output of the first converter 100.20 a value Vb.dx=0.13554 V and, on the basis of the aforementioned equation, i.e. (equation_1):

$$… um = \frac{Va . sx . Vb . dx . ( C 2. sx . C 3. dx + C 2. sx . C 2. dx - C 2. dx . C 3. dx )}{C 2. dx . ( Va . sx . C 2. sx - Vb . dx . C 3. dx )}$$

we will have as a calculation performed by the Microcontroller 100.40

$$… Um = 0.25312 V . 0.13554 V . ( 590 nF . 630 nF + 590 nF . 20 pF - 20 pF . 630 nF ) \text{} / ( 20 pF . ( 0.25312 V . 590 nF - 0.1 \; 3554 V . 630 nF ) )$$

whose result corresponds to
Um=9.970.2V.

### Second Calculation Example System 200.S of FIG. 2

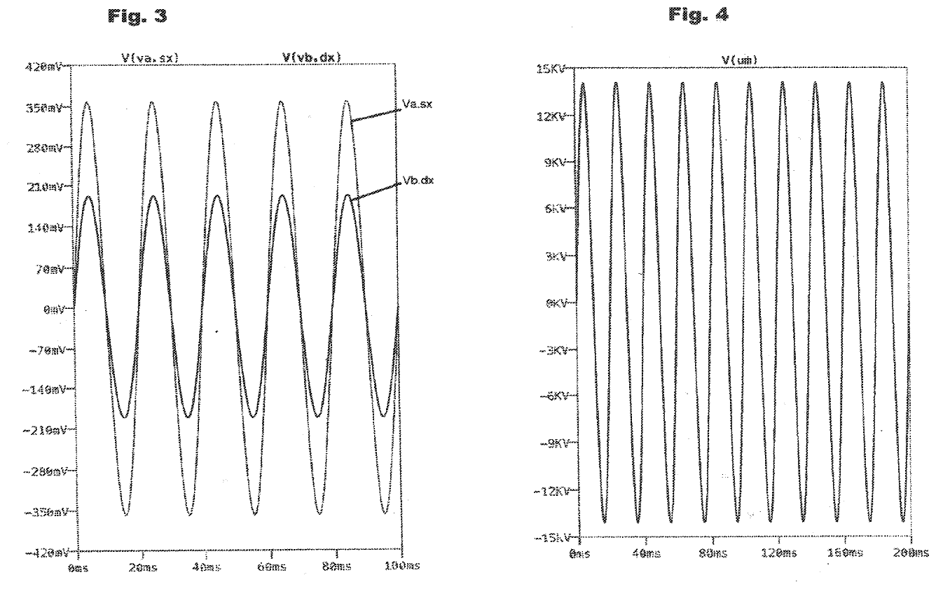

Again by way of example, with reference to the system 200.S of FIG. 2, using the components as indicated above, by applying the system 200.S to an element ET having voltage, the waveforms illustrated in FIG. 3 were detected. _The Real Time microcontroller divides the instantaneous voltages va.sx(t) and vb.dx(t) by the transformation ratio k, previously entered via keyboard 200.40 or other system and via the equation (equation_2):

$$um ( t ) = \frac{va . sx ( t ) . vb . dx ( t ) . ( C 2. sx . C 3. dx + C 2. sx . C 2. dx - C 2. dx . C 3. dx )}{C 2. dx . ( va . sx ( t ) . C 2. sx - vb . dx ( t ) . C 3. dx )}$$

was obtained the waveform illustrated in FIG. 4.

By means of the system object of the present invention a correct and/or safe estimate of the voltage value of the live element is maintained over time, simple and inexpensive maintenance can be performed since module_A does not require maintenance and the module_B can be located in an easily accessible place (such as for example inside an electrical substation) and, therefore, the maintenance and/or repair of said systems, for example in relation to Module_B, can be performed even if the element subject to measurement is live (for example by equipping the connection means MC1 and MC2 with disconnectors). _Furthermore, the repair and maintenance operations can be carried out, for example of the Module_B, by non highly specialized workers.

With reference to the above description, the term “module” MA is preferably used to define an independent unit of a complex comprising, for example, two or more modules MA and MB that can be connected together and/or two or more constructively independent units MA and MB connectable each other for example by means of conductors and/or an independent unit MA and other components connectable to said unit MA by means of conductors such as, for example

$$> \_MA + M B + 100.20 + 100.30 + 100.40 + 100.50 + 100 \text{.60} \qquad ( fig . 1 )$$

$$> \_MA + M B + 200.20 + 200.30 + 200.40 + 200.50 + 200.60 \qquad ( fig . 2 )$$

Again preferably, said module MA comprises specific and particular components as above described and, furthermore, said module MA is intended to perform a particular and specific function as part of an apparatus and/or a circuit and/or a complex and/or a system.

Again preferably, said MA module is made as an autonomous self-supporting unit, so that it can be easily removed and/or replaced and/or disconnected with respect to the respective apparatus and/or circuit and/or complex and/or system and, if desirable, said module MA can also provide a shield to protect the related components from the surrounding electric fields.

The description of the system specified above is given purely by way of non-limiting example and, therefore, it is evident that all those modifications or variations suggested by practice and by its use can be made to said system and, in any case, within the scope of scope of the following claims, which also form an integrative part for the present description.

1. A system for estimating the voltage value of a live element, the system comprising:
a first capacitor having a respective first pole and a second pole;
a second capacitor having a respective first pole and a second pole;
a third capacitor having a respective first pole and a second pole;
a fourth capacitor having a respective first pole and a second pole;
a fifth capacitor having a respective first pole and a second pole; by wherein
the first capacitor has its first pole connected to the live element,
the second capacitor has its first pole connected to the live element,
the third capacitor has its first pole connected to the second pole of the first capacitor and its second pole connected to ground
the fourth capacitor has its first pole connected to the second pole of the second capacitor and its second pole connected to the first pole of the fifth capacitor,
the fifth capacitor has its second pole connected to the ground,
the first capacitor has on its second pole or along the respective conductor connecting it to the third capacitor,
electric voltage here is the first value of electric voltage,
the fourth capacitor has on its second pole or along the respective conductor connecting it to the fifth capacitor a value of electric voltage defined here as the fourth value of electric voltage.

2. The system according to claim 1, wherein the first capacitor and the second capacitor are equal or identical to each other.

3. The system according to claim 1, wherein the first capacitor and the second capacitor have respective dielectric materials identical to each other or respective dielectric materials not identical to each other but having characteristics that change or mutate identically if the two not identical dielectric materials are subjected over time to the same functional or environmental or aging vicissitudes.

4. The system according to according to claim 1, wherein the fourth capacitor has an electric capacity value of the same order of magnitude as the first capacitor or of the second capacitor.

5. The system according to claim 1, wherein the first capacitor and the second capacitor are two capacitors having a predetermined ratio in relation to the values of the respective electric capacities.

6. The system according to claim 1, wherein the first capacitor and the second capacitor are connected or positioned or arranged in such a way that over the course of time, to the same operating or environmental or aging conditions.

7. The system according to according to claim 1, wherein the estimate of the value of electric voltage of the live element is calculated using the following values:
at least one value of electric voltage regarding to a first point/node positioned along the conductor that connects the first capacitor to the third capacitor;
at least one value of electric voltage regarding to a second point/node positioned along the conductor that connects the fourth capacitor to the fifth capacitor;
at least one capacitance value of the third capacitor;
at least one capacitance value of the fourth capacitor;
at least one capacitance value of the fifth capacitor.

8. The system according to claim 1, further comprising:
a first AC/RMS converter;
a second AC/RSM converter; and
a microcontroller.

9. The system according to according to claim 1, wherein the electrical voltage of the live element is calculated using the following equation
$$Um = \frac{Va . sx . Vb . dx . ( C 2. sx . C 3. dx + C 2. sx . C 2. dx - C 2. dx . C 3. dx )}{C 2. dx . ( Va . sx . C 2. sx - Vb . dx . C 3. dx )}$$
where
Um=effective value of the voltage of the live element ET;
Va.sx=effective value of the voltage regarding the second pole C1.sx.p2 of the first capacitor C1.sx or regarding a first node 1.N1 positioned along the conductor C1. sx. p2_MC1 C2. sx. p1 connecting the first capacitor C1.sx to the third capacitor C2.sx;
Vb.dx=effective value of the voltage regarding the second pole C2.dx.p2 of the fourth capacitor C2.dx or regarding a second node 1.N2 positioned along the conductor C2.dx.p2_C3.dx.p1 connecting the fourth capacitor C2.dx to the fifth capacitor C3.dx;
C2.sx=electric capacity value of the third capacitor C2.sx;
C2.dx=electric capacity value of the fourth capacitor C2.dx;
C3.dx=electric capacity value of the fifth capacitor C3.dx.

10. The system according to according to claim 1, further comprising:
a Microcontroller Real-Time; and
a Digital-Analog Converter.

11. The system according to claim 1, wherein the electrical voltage of the live element is calculated using the following equation
$$um ( t ) = \frac{va . sx ( t ) . vb . dx ( t ) . ( C 2. sx . C 3. dx + C 2. sx . C 2. dx - C 2. dx . C 3. dx )}{C 2. dx . ( va . sx ( t ) . C 2. sx - vb . dx ( t ) . C 3. dx )}$$
where
um (t)=Estimated value of instantaneous primary voltage of the live element;
va.sx (t)=Value of the instantaneous electric voltage of the second pole of the first capacitor or of a first node positioned along the conductor connecting the first capacitor to the third capacitor;
vb.dx (t)=Value of the instantaneous electric voltage of the second pole of the fourth capacitor or of a second node positioned along the conductor that connects the fourth capacitor with the fifth capacitor C3.dx;
C2.sx=electric capacity value of the third capacitor;
C3.dx=electric capacity value of the fifth capacitor
C2.dx=electric capacity value of the fourth capacitor.

12. The system according to claim 1,
further comprising:
a first module);
a second module;
means of connection;
the first module having
at least a first capacitor and
a second capacitor;
the second module having other components; by first module being positioned separately and independently with respect to the second module; and
the means of connection connecting the first module with respect to the second module.

13. The system according to claim 1,
further comprising:
a first module;
a second module;
first means of connection;
second means of connection; the first module having at least the first capacitor and the second capacitor,
the second module having at least the third capacitor, the fourth capacitor and the fifth capacitor;
the first module can being positioned separately and independently with respect to the second module,
the first connection means connecting the second pole of the first capacitor with the first pole of the third capacitor
the second connection means connecting the second pole of the second capacitor with the first pole of the fourth capacitor.

14. The system according to claim 12, wherein the first module is positioned such that the first capacitor and the second capacitor are subjected to the same vicissitudes over time.

15. The system according to to claim 1.
